(19) United States
(12) Patent Application Publication
(10) Pub. No.: US 2011/0156836 A1
(43) Pub. Date: Jun. 30, 2011

(54) DUPLEXER DEVICE AND METHOD OF MANUFACTURING THE SAME

(75) Inventors: Yeong Gyu LEE, Suwon (KR); Yong Deuk YE, Yongin (KR); Je Hong KYOUNG, Seongnam (KR); Chan Bong JUN, Seoul (KR)

(73) Assignee: SAMSUNG ELECTRO-MECHANICS CO., LTD., Suwon (KR)

(21) Appl. No.: 12/843,394

(22) Filed: Jul. 26, 2010

(30) Foreign Application Priority Data
Dec. 30, 2009 (KR) 1020090134441

(51) Int. Cl. H03H 9/72

(52) U.S. Cl. 333/133

(57) ABSTRACT

There is provided a duplexer device and a method of manufacturing the same. The duplexer device includes a substrate including a duplex circuit; first and second acoustic wave filter chips mounted on the substrate in a flip chip bonding manner and constituting an Rx (receiver) filter and a Tx (transmitter) filter, respectively; and a molding portion covering the first and second acoustic wave filter chips. The first and second acoustic wave filter chips are arranged by flip chip bonding, so there is no need for a separate protective structure so as to protect device functional portions of the chips. Accordingly, a compact product is realized and a manufacturing process is simplified.

### CROSS-REFERENCE TO RELATED APPLICATIONS

This application claims the priority of Korean Patent Application No. 10-2009-0134441 filed on Dec. 30, 2009, in the Korean Intellectual Property Office, the disclosure of which is incorporated herein by reference.

### BACKGROUND OF THE INVENTION

1. Field of the Invention

The present invention relates to a duplexer device and a method of manufacturing the same, and more particularly, to a duplexer device capable of being miniaturized and allowing for a reduction in manufacturing costs as well as an increase in yield rate by simplifying a manufacturing process and a method of manufacturing the same.

2. Description of the Related Art

With the continued development of the telecommunications industry, current trends are for wireless communications products to be miniaturized while retaining high quality and multi-functionality. In light of such trends, there is current demand for the miniaturization and improvement of the quality of components used in wireless communications products.

In order to satisfy the demand for miniaturization, currently, studies have been undertaken in the area of manufacturing an essential wireless communications device component, such as a filter and a duplexer, by using Film Bulk Acoustic Resonators (FBARs) that are advantageous in integration due to their thin film shapes and have good properties.

In general, an FBAR chip is formed in such a fashion that a piezoelectric layer is formed on a wafer, and upper and lower electrodes are formed on upper and lower portions of the piezoelectric layer, respectively, for applying electricity to the piezoelectric layer so as to induce oscillations therein. Further, a desired air gap is formed under the piezoelectric layer in order to improve the resonance properties of the piezoelectric layer.

A duplexer device has at least two FBAR chips, mounted on a substrate serving as a lower support, for forming a Tx (transmitter) filter and an Rx (receiver) filter, respectively. The substrate is formed to include a common terminal and transmitting/receiving terminals, and circuit patterns for electrically connecting the terminals to the Tx and Rx filters. Further, in order to achieve a complete sealing of the FBAR chips, a molding portion is formed on the substrate.

A protective structure is provided to protect device functional portions, that is, a piezoelectric layer, an air gap, and an electrode, of the FBAR chip, from the above molding process. The protective structure may be formed by processing a wafer having a predetermined thickness using a wafer level package (WLP) technique, and bonding the processed wafer onto the substrate having the FEAR chip mounted thereon. In the case that the FBAR chip and the protective structure are formed as stated above, however, the overall structure and manufacturing process of the duplexer device are disadvantageously complex, since the protective structure should be configured so as to be electrically connected to the device functional portions inside the FBAR chip while serving to protect the device functional portions.

Also, a duplexer device has a plurality of ceramic sheets stacked by using a Low Temperature Co-fired Ceramic (LTCC) technique to form an LTCC substrate that includes a cavity therein. Then, a FBAR chip is mounted in the cavity. After electrically connecting the FBAR chip to the LTCC substrate by wire bonding, a metal lead is fused to or seam-sealed on the LTCC substrate.

In this case, it is necessary to ensure that the spaces required for wire bonding and sealing that is performed for protecting the FBAR chip are provided. This causes the problem of an increase in product size.

### SUMMARY OF THE INVENTION

An aspect of the present invention provides a duplexer device capable of being miniaturized and allowing for a reduction in manufacturing costs as well as an increase in yield rate by simplifying a manufacturing process and a method of manufacturing the same.

According to an aspect of the present invention, there is provided a duplexer device including: a substrate including a duplex circuit; first and second acoustic wave filter chips mounted on the substrate in a flip chip bonding manner and constituting an Rx (receiver) filter and a Tx (transmitter) filter, respectively; and a molding portion covering the first and second acoustic wave filter chips.

The first and second acoustic wave filter chips may be a surface acoustic wave (SAW) chip and a film bulk acoustic resonator (FBAR) chip, respectively.

The Rx filter may be constituted of a surface acoustic wave (SAW) chip and the Tx filter may be constituted of a film bulk acoustic resonator (FBAR) chip.

Each of the first and second acoustic wave filter chips may include a chip substrate having an air gap, a piezoelectric layer provided on a surface of the chip substrate having the air gap, an electrode provided on the piezoelectric layer, and a plurality of bump balls provided on a bottom of the electrode and bonded onto a top of the substrate.

The substrate may be a Low Temperature Co-fired Ceramic (LTCC) substrate or a High Temperature Co-fired Ceramic (HTCC) substrate.

The molding portion may be formed of epoxy or engineering plastic.

According to another aspect of the present invention, there is provided a method of manufacturing a duplexer device, the method including: preparing a substrate including a duplex circuit; mounting first and second acoustic wave filter chips on the substrate in a flip chip bonding manner, the first and second acoustic wave filter chips constituting an Rx (receiver) filter and a Tx (transmitter) filter, respectively; and forming a molding portion to cover the first and second acoustic wave filter chips.

The substrate may be formed by a Low Temperature Co-fired Ceramic (LTCC) process or a High Temperature Co-fired Ceramic (HTCC) process.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view illustrating a duplexer device according to an exemplary embodiment of the present invention;

FIG. 2 is a schematic block diagram illustrating the structure of a duplexer device according to an exemplary embodiment of the present invention; and

FIGS. 3A through 3C are cross-sectional views illustrating a sequential process of manufacturing a duplexer device according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements maybe exaggerated for clarity, and the same reference numerals will be used throughout to designate the same or like elements.

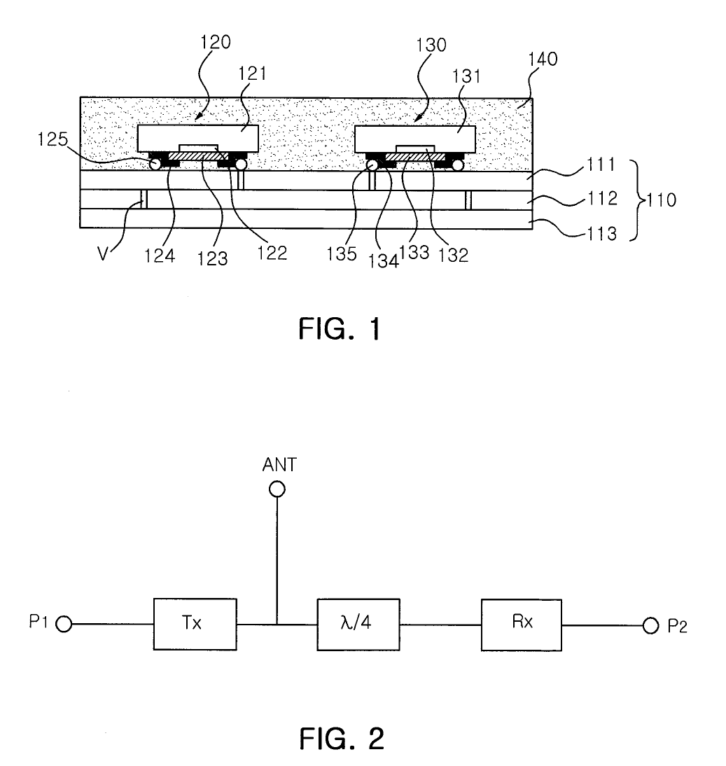

FIG. 1 is a schematic cross-sectional view illustrating a duplexer device according to an exemplary embodiment of the present invention. With reference to FIG. 1, a duplexer device includes a substrate 110, first and second acoustic wave filter chips 120 and 130 mounted on the substrate 110 in a flip chip bonding manner and formed as an Rx (receiver) filter and a Tx (transmitter) filter, respectively, and a molding portion 140 covering the first and second acoustic wave filter chips 120 and 130.

The substrate 110 includes a duplex circuit. More specifically, the substrate 110 is embodied to include a common terminal and transmitting/receiving terminals, and circuit patterns for electrically connecting the terminals to the Rx filter and the Tx filter.

That is, as shown in FIG. 2, the substrate 110 includes the Rx and Tx filters for transmitting/receiving band pass, a phase shifter λ/4 connected between the Rx and Tx filters, and external terminals P1 and P2 respectively connected to the Tx and Rx filters.

The substrate 110 may be a Low Temperature Co-fired Ceramic (LTCC) substrate or a High Temperature Co-fired Ceramic (HTCC) substrate, each of which includes a multilayer circuit pattern.

More specifically, the substrate 110 may include a first sheet 111, a second sheet 112, and a third sheet 113. The circuit patterns formed on the sheets maybe connected through via electrodes V.

The first and second acoustic wave filter chips 120 and 130 are different-type filter chips and constitute the Rx and Tx filters, respectively. The first acoustic wave filter chip 120 includes a chip substrate 121 of a predetermined size having an air gap 122, a piezoelectric layer 123 formed on a surface of the chip substrate 121 having the air gap 122, an electrode 124 formed on the piezoelectric layer 123 so as to be electrically connected thereto for signal input/output, and a plurality of bump balls 125 formed on the bottom of the electrode 124 and bonded onto the top of the substrate 110. The second acoustic wave filter chip 130 includes a chip substrate 131 of a predetermined size having an air gap 132, a piezoelectric layer 133 formed on a surface of the chip substrate 131 having the air gap 132, an electrode 134 formed on the piezoelectric layer 133 so as to be electrically connected thereto for signal input/output, and a plurality of bump balls 135 formed on the bottom of the electrode 134 and bonded onto the top of the substrate 110.

That is, the first acoustic wave filter chip 120 includes the chip substrate 121, the air gap 122 and the piezoelectric layer 123 that are sequentially arranged. After the bump balls 125 are formed on the electrode 124 electrically connected to the piezoelectric layer 123, the first acoustic wave filter chip 120 is reversed in order that the chip substrate 121 is located at the uppermost position, and the bump balls 125 are then bonded to the substrate 110. The second acoustic wave filter chip 130 includes the chip substrate 131, the air gap 132 and the piezoelectric layer 133 that are sequentially arranged. After the bump balls 135 are formed on the electrode 134 electrically connected to the piezoelectric layer 133, the second acoustic wave filter chip 130 is reversed in order that the chip substrate 131 is located at the uppermost position, and the bump balls 135 are then bonded to the substrate 110.

Here, since the chip substrate 121 is located at the uppermost position, the chip substrate 121 may serve as an upper cover. Further, due to the thickness of the bump balls 125, a gap is present between the piezoelectric layer 123 of the first acoustic wave filter chip 120 and the substrate 110.

Therefore, when the molding portion 140 is formed around the first and second acoustic wave filter chips 120 and 130 that are mounted in a flip chip bonding manner as stated above, it is unnecessary to form a separate protective structure so as to protect device functional portions, that is, the piezoelectric layers, the air gaps and the electrodes of the acoustic wave filter chips.

The first and second acoustic wave filter chips 120 and 130 may be a surface acoustic wave (SAW) chip and a film bulk acoustic resonator (FBAR) chip, respectively. More specifically, the Rx filter may be constituted of an SAW chip and the Tx filter may be constituted of an FBAR chip.

The molding portion 140 may be formed by applying a sealing material and the like to the substrate 110 so as to cover the two acoustic wave filter chips 120 and 130, and hardening the applied sealing material. The molding portion 140 may be formed of epoxy or engineering plastic.

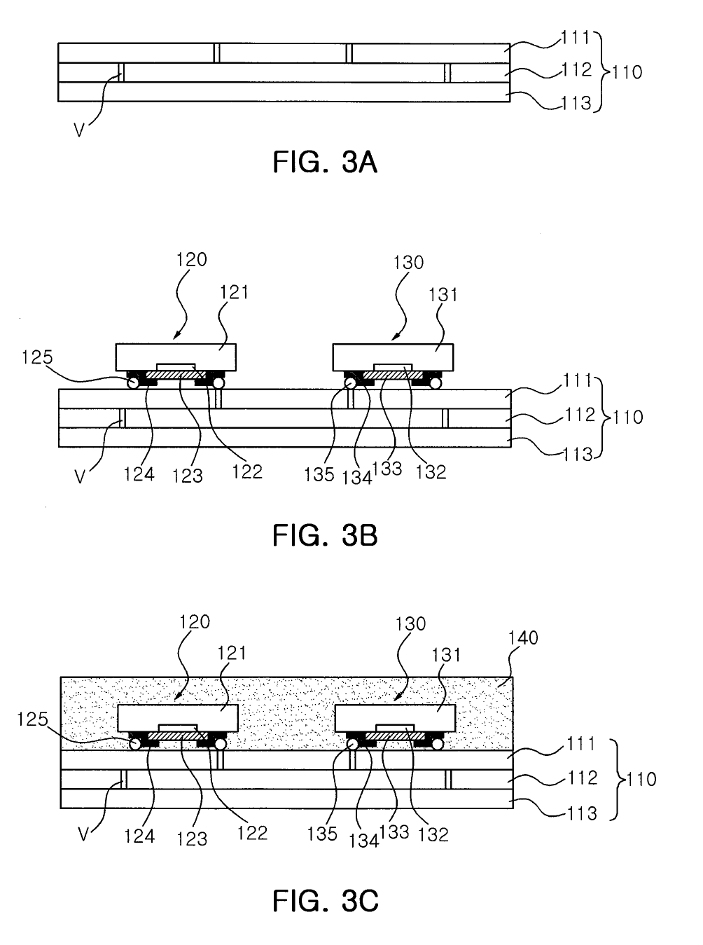

FIGS. 3A through 3C are cross-sectional views illustrating a sequential process of manufacturing a duplexer device according to an exemplary embodiment of the present invention.

Hereinafter, a method of manufacturing a duplexer device according to this embodiment will be described with reference to FIGS. 3A through 3C.

First, as shown in FIG. 3A, the substrate 110 is formed such that a plurality of ceramic sheets 111, 112, and 113 include circuit patterns and via electrodes V for the connection of the circuit patterns and are laminated to thereby realize a duplex circuit.

The substrate 110 may be a ceramic substrate manufactured by using an LTCC process or an HTCC process.

Next, as shown in FIG. 3B, the acoustic wave filter chips 120 and 130 are mounted on the substrate 110 in a flip chip bonding manner.

The first acoustic wave filter chip 120 includes the chip substrate 121, the air gap 122 formed on a surface of the chip substrate 121, the piezoelectric layer 123 and the electrode 124.

The first acoustic wave filter chip 120 may be formed by a variety of well-known methods in the art. For example, a wafer having a predetermined area is first divided into a plurality of wafer sections in rows and columns. Sacrificial layers are formed on the wafer sections, respectively. After piezoelectric layers are respectively formed on the sacrificial layers, electrodes are respectively formed on the wafer sections of the wafer to be electrically connected to the piezoelectric layers. Then, the sacrificial layers are removed so that the air gaps and the piezoelectric layers may be formed to be vertically arranged. Then, bump balls are respectively formed on the electrodes of the wafer.

As stated above, the formation of the bump balls 125 at the level of the wafer may be achieved through a single process, regardless of the number of chips. This is more advantageous than a method of forming bump balls on individual chips. Then, the wafer having the air gaps 122, the piezoelectric layers 123, the electrodes 124 and the bump balls 125 formed thereon is cut along predetermined cutting lines, thereby manufacturing individual chips 120.

The plurality of chips 120 are mounted on the substrate 110 in a flip chip bonding manner by allowing the chip substrates 121 of the plurality of chips 120 to face upward and allowing the bump balls 125 to face the substrate 110.

The second acoustic wave filter chip 130 may be formed by the same method as the first acoustic wave filter chip 120 and be mounted on the substrate 110 in the same flip chip bonding manner.

Then, as shown in FIG. 3C, the molding portion 140 is formed to cover the first and second acoustic wave filter chips 120 and 130.

The molding portion 140 may be formed of a sealing material such as epoxy or engineering plastic. After forming the molding portion using the sealing material and hardening the sealing material, a duplexer device package is manufactured.

As set forth above, according to exemplary embodiments of the invention, in a duplexer device according to exemplary embodiments of the invention, different-type acoustic wave filter chips are arranged by flip chip bonding, so there is no need for a separate protective structure so as to protect device functional portions, that is, piezoelectric layers, air gaps and electrodes of the chips. Accordingly, a compact product is realized and a manufacturing process is simplified.

While the present invention has been shown and described in connection with the exemplary embodiments, it will be apparent to those skilled in the art that modifications and variations can be made without departing from the spirit and scope of the invention as defined by the appended claims.

What is claimed is:

1. A duplexer device comprising:
a substrate including a duplex circuit;
first and second acoustic wave filter chips mounted on the substrate in a flip chip bonding manner and constituting an Rx (receiver) filter and a Tx (transmitter) filter, respectively; and
a molding portion covering the first and second acoustic wave filter chips.

2. The duplexer device of claim 1, wherein the first and second acoustic wave filter chips are a surface acoustic wave (SAW) chip and a film bulk acoustic resonator (FBAR) chip, respectively.

3. The duplexer device of claim 1, wherein the Rx filter is constituted of a surface acoustic wave (SAW) chip and the Tx filter is constituted of a film bulk acoustic resonator (FBAR) chip.

4. The duplexer device of claim 1, wherein each of the first and second acoustic wave filter chips includes a chip substrate having an air gap, a piezoelectric layer provided on a surface of the chip substrate having the air gap, an electrode provided on the piezoelectric layer, and a plurality of bump balls provided on a bottom of the electrode and bonded onto a top of the substrate.

5. The duplexer device of claim 1, wherein the substrate is a Low Temperature Co-fired Ceramic (LTCC) substrate or a High Temperature Co-fired Ceramic (HTCC) substrate.

6. The duplexer device of claim 1, wherein the molding portion is formed of epoxy or engineering plastic.

7. A method of manufacturing a duplexer device, the method comprising:
preparing a substrate including a duplex circuit;
mounting first and second acoustic wave filter chips on the substrate in a flip chip bonding manner, the first and second acoustic wave filter chips constituting an Rx (receiver) filter and a Tx (transmitter) filter, respectively; and
forming a molding portion to cover the first and second acoustic wave filter chips.

8. The method of claim 7, wherein the substrate is formed by a Low Temperature Co-fired Ceramic (LTCC) process or a High Temperature Co-fired Ceramic (HTCC) process.
